(19) United States
(12) Patent Application Publication
(10) Pub. No.: US 2013/0001614 A1
(43) Pub. Date: Jan. 3, 2013

(54) LIGHT-EMITTING DIODE DEVICE AND METHOD FOR FABRICATING THE SAME

(75) Inventors: Hsin-Ming LO, Pingtung County (TW); Shih-Chang Shei, Tainan City (TW)

(73) Assignee: ACEPLUX OPTOTECH INC., Tainan City (TW)

(21) Appl. No.: 13/348,779

(22) Filed: Jan. 12, 2012

(30) Foreign Application Priority Data
Jun. 30, 2011 (TW) 100123148

(51) Int. Cl. H01L 33/42; H01L 33/60

(52) U.S. Cl. 257/98; 438/29; 257/E33.072; 257/E33.064

(57) ABSTRACT

A light-emitting diode device includes: a substrate including first and second conductors; a light-emitting diode die including first and second polarity sides, and a surrounding surface formed between the first and second polarity sides; an insulator disposed around the surrounding surface; a transparent conductive layer extending from the second polarity side of the light-emitting diode die oppositely of the substrate, along an outer surface of the insulator, and to the second conductor; and a reflecting cup formed on the substrate to define a space with the substrate. The light-emitting diode die, the insulator and the transparent conductive layer are disposed in the space.

### CROSS-REFERENCE TO RELATED APPLICATION

This application claims priority of Taiwanese Patent application no. 100123148, filed on Jun. 30, 2011.

### BACKGROUND OF THE INVENTION

1. Field of the Invention

The present invention relates to a light-emitting diode device and a method for fabricating the same, more particularly to a light-emitting diode device having a relatively large light emitting area and a method for fabricating the same.

2. Description of the Related Art

In recent years, light-emitting diodes (LEDs) have attracted much attention due to their properties of compact structure, low power consumption, simple construction and easy mounting. One of the main studies for LEDs focuses on improvement in brightness and light-extracting rate of LEDs.

Referring to FIG. 1, a conventional light-emitting diode die 12 is obtained by cutting a wafer and comprises a substrate 121, an epitaxial film 122 that is formed on the substrate 121 and that may emit light while receiving electricity, and two electrodes 123 formed on the epitaxial film 122.

In consideration of the epitaxial quality of a commonly used gallium nitride-based semiconductor, the substrate 121 is made of sapphire. The epitaxial film 122 is made of a gallium nitride-based semiconductor material, and includes an n-cladding layer, a quantum well structure, and a p-cladding layer so as to convert electricity into light by virtue of photoelectrical effect. In addition, the epitaxial film 122 of the light-emitting diode die 12 is normally further provided with a current spreading layer that is mainly made of a metal oxide so as to achieve a more uniform current distribution in the epitaxial film 122. Since the current spreading layer is well known to one of ordinary skill in the art, a description thereof is omitted herein.

The two electrodes 123 are disposed on and are electrically connected to the epitaxial film 122. The two electrodes 123 are adapted to be electrically connected to a lead frame through wires in a subsequent packaging process, thereby connecting to an external circuit (not shown).

Referring to FIG. 2, a conventional package structure 1 is shown to include the aforesaid conventional light-emitting diode die 12, a cup member 11 made of a reflective material and including a receiving space 110, two wires 13, an encapsulant 14, and a lead frame 113.

The lead frame 113 has a first conductor 111 and a second conductor 112. The first conductor 111 and the second conductor 112 are spaced apart from each other and are adapted to connect to the external circuit.

The two wires 13 are made of an electrically conductive material, such as gold (Au), and thus are also known as gold wires. The wires 13 are used to electrically connect the electrodes 123 of the light-emitting diode die 12 to the first conductor 111 and the second conductor 112 after the light-emitting diode die 12 is disposed in the receiving space 110 of the cup member 11. In this way, electricity from the external circuit may be supplied to the light-emitting diode die 12 through the first and second conductors 111, 112, and the wires 13, thereby generating light in the epitaxial film 122 by virtue of photoelectric effect.

The encapsulant 14 is filled in the receiving space 110 of the cup member 11 so as to encapsulate the light-emitting diode die 12 in the receiving space 110. Thus, the light-emitting diode die 12 may be protected from being damaged by external environmental factors, such as moisture, without blocking light emission, thereby prolonging the service life of the light-emitting diode die 12. In addition, the encapsulant 14 usually includes fluorescent powders that are excited by the light emitting from the epitaxial film 122 to produce light within a predetermined wavelength range, thereby permitting the package structure 1 to emit desired mixed light.

The package structure 1 including the conventional light-emitting diode die 12 has a light emitting function. However, since the electrodes 123 of the light-emitting diode die 12 are not light transmissive, they will block a part of light emitting from the epitaxial film 122 of the light-emitting diode die 12. In addition, the wires 13 might also block the light, thereby resulting in reduced light emitting uniformity.

Moreover, in the conventional package structure 1, since the cup member 11 is made by a mechanical process, e.g., an injection molding process, line-width limitation occurs, and the package structure 1 thus has relatively large dimensions.

### SUMMARY OF THE INVENTION

Therefore, the object of the present invention is to provide a light-emitting diode device that can increase the light emitting area so as to enhance the brightness thereof.

Another object of the present invention is to provide a method for fabricating a light-emitting diode device that can increase the light emitting area so as to enhance the brightness thereof.

Accordingly, a light-emitting diode device of the present invention comprises: a substrate including first and second conductors that are spaced apart from each other and that are adapted for connection to an external circuit; a light-emitting diode die disposed on the substrate and including first and second polarity sides that have opposite polarities, and a surrounding surface that is formed between the first and second polarity sides, the first polarity side being electrically connected to the first conductor; an insulator disposed around the surrounding surface of the light-emitting diode die; a transparent conductive layer extending from the second polarity side of the light-emitting diode die oppositely of the substrate, along an outer surface of the insulator, and to the second conductor, so that the second polarity side is electrically connected to the second conductor through the transparent conductive layer; and a reflecting cup formed on the substrate to define a space with the substrate, the light-emitting diode die, the insulator and the transparent conductive layer being disposed in the space.

According to the present invention, a method for fabricating a light-emitting diode device comprises: (a) forming over a temporary substrate a light-emitting diode die which has first and second polarity sides having opposite polarities, and a surrounding surface that is formed between the first and second polarity sides; (b) preparing a permanent substrate which includes an insulating base, and first and second conductors that are separately formed on the insulating base; (c) mounting the light-emitting diode die on the permanent substrate such that the first polarity side of the light-emitting diode die, which is disposed opposite to the temporary substrate, is electrically connected to the first conductor of the permanent substrate, and the light-emitting diode die is spaced apart from the second conductor, followed by removing the temporary substrate to expose the second polarity side of the light-emitting diode die; (d) forming an insulator to surround the surrounding surface of the light-emitting diode die; (e) forming a transparent conductive layer that extends from the second polarity side of the light-emitting diode die, along an outer surface of the insulator, to the second conductor, so that the second polarity side of the light-emitting diode die is electrically connected to the second conductor through the transparent conductive layer; and (f) forming a reflecting cup on the permanent substrate to enclose the light-emitting diode die, the insulator, and the transparent conductive layer.

### BRIEF DESCRIPTION OF THE DRAWINGS

Other features and advantages of the present invention will become apparent in the following detailed description of the preferred embodiments with reference to the accompanying drawings, of which:

FIG. 1 is a cross sectional diagram of a conventional light-emitting diode die;

FIG. 2 is a fragmentary partly cross sectional diagram of a package structure including the conventional light-emitting diode device shown in FIG. 1;

FIG. 3 is a fragmentary partly cross sectional diagram of the preferred embodiment of a light-emitting diode device according to the present invention;

FIG. 4 is a fragmentary partly cross sectional diagram showing mounting of the preferred embodiment shown in FIG. 3 on a lead frame by a wire bonding technique;

FIG. 5 is a fragmentary partly cross sectional diagram showing mounting of the preferred embodiment shown in FIG. 3 on a lead frame by a flip chip technique;

FIG. 6 is a cross sectional diagram of a step of a method for fabricating the light-emitting diode device of the preferred embodiment according to the present invention, in which a light-emitting diode die is formed over a temporary substrate;

FIG. 7 is a fragmentary partly cross sectional diagram illustrating a step of the method for fabricating the light-emitting diode device of the preferred embodiment according to the present invention, in which the light-emitting diode die that is formed over the temporary substrate is mounted on a permanent substrate;

FIG. 8 is a fragmentary partly cross sectional diagram illustrating a step of the method for fabricating the light-emitting diode device of the preferred embodiment according to the present invention, in which the temporary substrate is removed from the light-emitting diode die;

FIG. 9 is a fragmentary partly cross sectional diagram illustrating a step of the method for fabricating the light-emitting diode device of the preferred embodiment according to the present invention, in which an insulator is formed around a surrounding surface of the light-emitting diode die;

FIG. 10 is a fragmentary partly cross sectional diagram illustrating a step of the method for fabricating the light-emitting diode device of the preferred embodiment according to the present invention, in which a transparent conductive layer is formed so as to connect the light-emitting diode die to a second conductor of the permanent substrate; and

FIG. 11 is a fragmentary partly cross sectional diagram illustrating a step of the method for fabricating the light-emitting diode device of the preferred embodiment according to the present invention, in which a reflecting cup is formed on the permanent substrate.

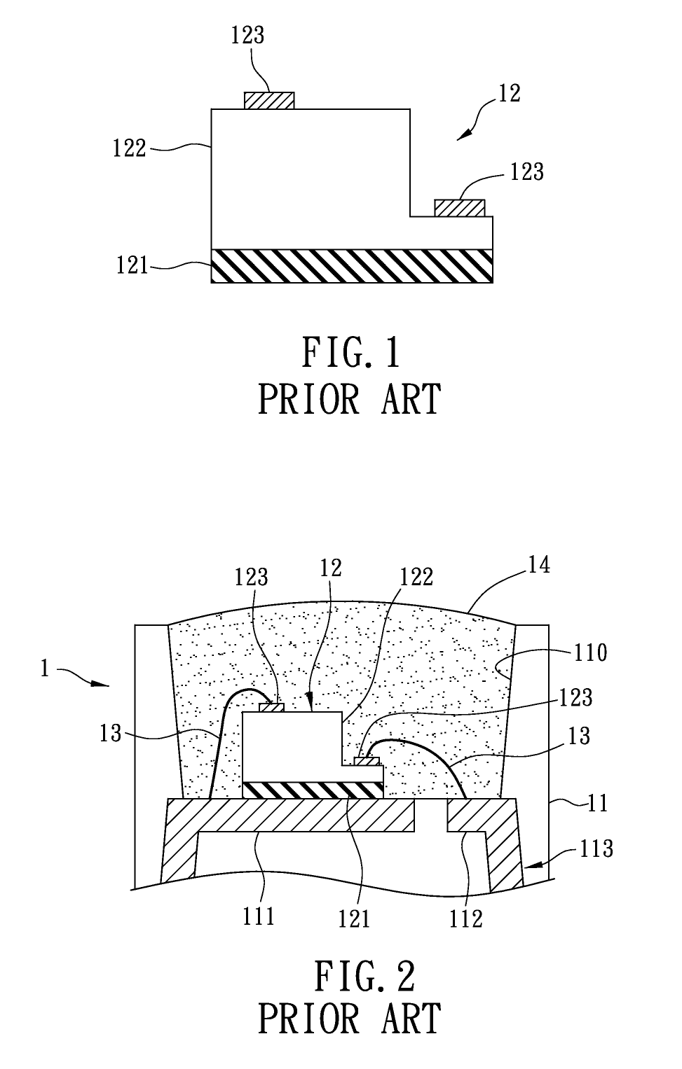

### DETAILED DESCRIPTION OF THE PREFERRED EMBODIMENTS

Before the present invention is described in greater detail, it should be noted that like components are assigned the same reference numerals throughout the following disclosure.

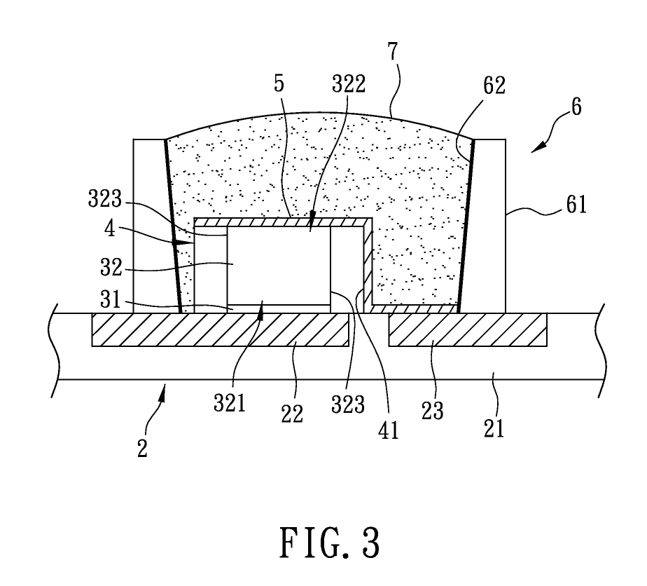

Referring to FIG. 3, the preferred embodiment of a light-emitting diode device of the present invention is produced in a batch process by means of a semiconductor technique and microelectromechanical systems (MEMS), which will be described in detail later. The light-emitting diode device comprises a substrate 2, an electrode layer 31, a light-emitting diode die 32, an insulator 4, a transparent conductive layer 5, a reflecting cup 6, and a light-transmissive encapsulant 7.

The substrate 2 includes an insulating base 21 and first and second conductors 22, 23. The first and second conductors 22, 23 are spaced apart from each other at the surface of the insulating base 21 and are adapted for electrical connection to an external circuit (not shown).

The light-emitting diode die 32 is disposed on the substrate 2 and includes first and second polarity sides 321, 322 that have opposite polarities, and a surrounding surface 323 that is formed between the first and second polarity sides 321, 322. The first polarity side 321 is electrically connected to the first conductor 22. The electrode layer 31 is disposed between the light-emitting diode die 32 and the substrate 2 to electrically connect the first polarity side 321 of the light-emitting diode die 32 and the first conductor 22. The electrode layer 31 is formed by an alloy material and is in ohmic contact with the light-emitting diode die 32 so as to achieve better and more stable electrical transmission. In addition, the electrode layer 31 may have a high reflectance with respect to the light that emits from the light-emitting diode die 32 so as to increase the amount of light emitting outwardly.

The insulator 4 is disposed around the surrounding surface 323 of the light-emitting diode die 32 and the electrode layer 31 so that the electrode layer 31 and the light-emitting diode die 32 are not in ohmic contact with the second conductor 23. Preferably, the insulator 4 is made of a transparent insulating material, for example, silicon oxide, silicon oxynitride, and magnesium fluoride, so that the insulator 4 can provide good insulating effect but not block the light emitting outwardly from the surrounding surface 323 of the light-emitting diode die 32.

The transparent conductive layer 5 may be formed by means of a vapor deposition process, e.g., a physical vapor deposition process. The transparent conductive layer 5 contacts and extends from the second polarity side 322 of the light-emitting diode die 32 oppositely of the substrate 2, along an outer surface 41 of the insulator 4, and to the second conductor 23, so that the second polarity side 322 is electrically connected to the second conductor 23 through the transparent conductive layer 5.

Preferably, the transparent conductive layer 5 has a thickness not less than 200 nm (measured from the top of the light-emitting diode die 32). If the thickness of the transparent conductive layer 5 is too small, the electrical conductivity may be insufficient and the resistance may be too large, thereby resulting in a decrease in light efficiency, inferior current distribution in the light-emitting diode die 32, and poor light emitting uniformity. More preferably, the transparent conductive layer 5 has a thickness not less than 300 nm. Furthermore, the transparent conductive layer 5 is made of a commonly used transparent conductive metal oxide, such as indium tin oxide, indium oxide, tin oxide, nickel oxide, zinc oxide, or magnesium oxide. The transparent conductive metal oxide allows light transmission and current to be distributed more uniformly, thereby improving the light emitting effect.

The reflecting cup 6 includes a surrounding wall 61 that surrounds the light-emitting diode die 32, the insulator 4 and the transparent conductive layer 5, and a reflecting layer 62 that is formed on an inner surface of the surrounding wall 61. The surrounding wall 61 is made of a photoresist material, and the reflecting layer 62 is formed by sputtering a reflective material selected from the group consisting of reflective metals, reflective alloys, and combinations thereof. Therefore, the light emitting from the surrounding surface 323 of the light-emitting diode die 32 may be reflected at least once by the reflecting layer 62 of the reflecting cup 6 and emitted outwardly, thereby increasing light extraction rate and brightness of the light-emitting diode device.

The light-transmissive encapsulant 7 is filled in a space defined by the reflecting cup 6 and the substrate 2 by a dispensing process to encapsulate the light-emitting diode die 32, the insulator 4 and the transparent conductive layer 5 so as to isolate the same from the external environment, for example, moisture, thereby enhancing the light emitting performance and prolonging the service life of the light-emitting diode device. In addition, the light-transmissive encapsulant 7 includes light-transmissive colloid and fluorescent powders that are excited by the light emitting from the light-emitting diode die 32 to produce light within a predetermined wavelength range, thereby permitting the light-emitting diode device to emit various mixed lights for subsequent applications.

When current is supplied from the external circuit (not shown) to the light-emitting diode device, by virtue of the isolation of the insulator 4, a one-way electrical path from the first conductor 22, through the electrode layer 31, the light-emitting diode die 32, the transparent conductive layer 5 and to the second conductor 23 is formed. Thus, electricity can be transmitted to the light-emitting diode die 32 and can be converted to light by virtue of photoelectric effect.

Since there is only the light-transmissive encapsulant 7 between the light-emitting diode die 32 and the external environment, the light emitting from the top of the light-emitting diode die 32 will be completely emitted outwardly without being blocked. In addition, the light emitting from the surrounding surface 323 may be reflected by the reflecting layer 62 of the reflecting cup 6 and then be emitted outwardly, thereby enhancing the light emitting efficiency of the light-emitting diode device.

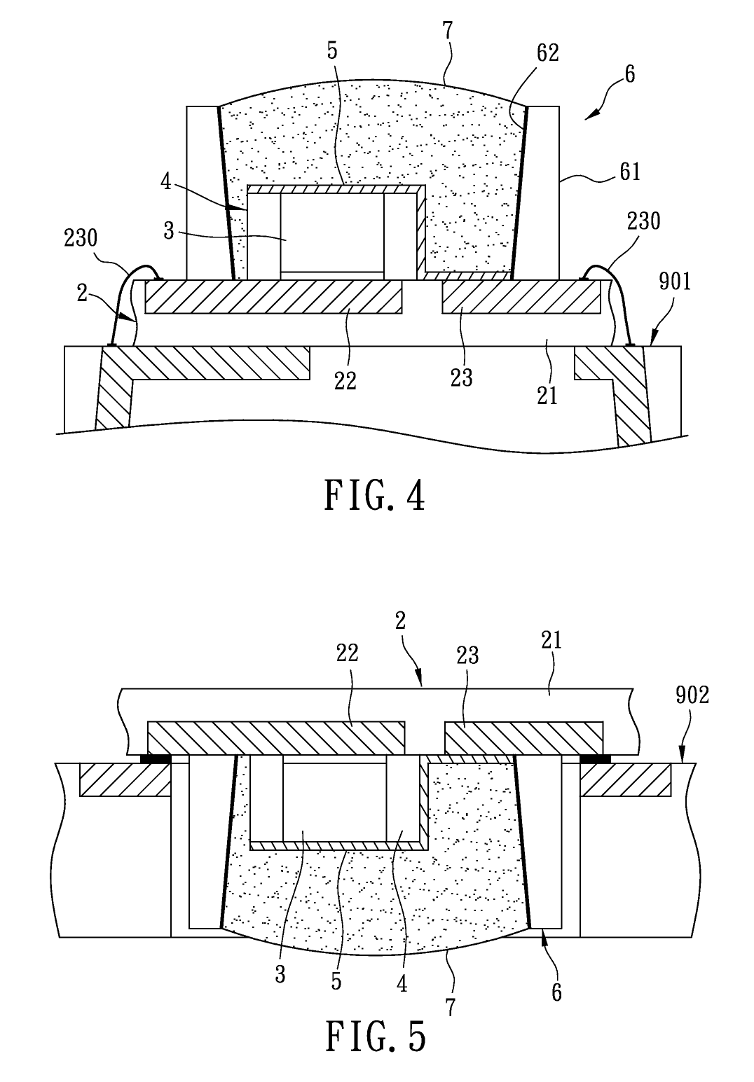

Referring to FIG. 4, the light-emitting diode device of the present invention may be mounted on a conventional lead frame 901 and electrically connected to the conventional lead frame 901 through wires 230 so as to form a package structure. Alternatively, referring to FIG. 5, the light-emitting diode device of the present invention may be mounted on and electrically connected to a circuit board 902 by means of a flip chip method. However, in either case, there are no light-blocking wires and opaque electrodes on the light-emitting diode die 32, so that superior light extraction rate and brightness of the package structure can be achieved.

A method for fabricating a light-emitting diode device of the preferred embodiment according to the present invention will now be described. It is noted that although the light-emitting diode device of the preferred embodiment is described as a single light-emitting diode device in the method for fabricating the light-emitting diode device according to the present invention, the method can be performed on a wafer including a plurality of dies, followed by cutting the wafer into individual light-emitting diode dies.

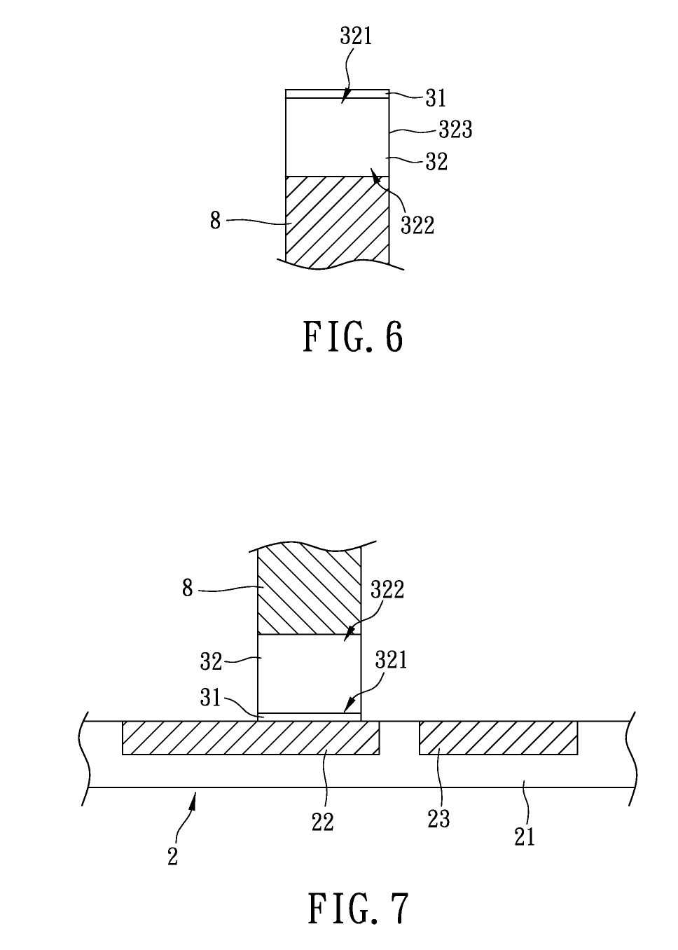

Referring to FIG. 6, the method for fabricating the light-emitting diode device according the present invention comprises forming over a temporary substrate 8, for example a sapphire substrate, a light-emitting diode die 32 which has first and second polarity sides 321, 322 that have opposite polarities, and a surrounding surface 323 that is formed between the first and second polarity sides 321, 322. An electrode layer 31 is then formed over the first polarity side 321 oppositely of the temporary substrate 8, so that the interface of the electrode layer 31 and the light-emitting diode die 32 forms an ohmic contact for achieving good current conduction.

Referring to FIG. 7, a permanent substrate 2 is provided. The permanent substrate 2 includes an insulating base 21, and first and second conductors 22, 23 that are separately formed on the insulating base 21. The assembly of the temporary substrate 8, the light-emitting diode die 32, and the electrode layer 31 is mounted to the permanent substrate 2 such that the first polarity side 321 of the light-emitting diode die 32, which is disposed opposite to the temporary substrate 8, is electrically connected to the first conductor 22 of the permanent substrate 2 through the electrode layer 31, and the light-emitting diode die 32 is spaced apart from the second conductor 23.

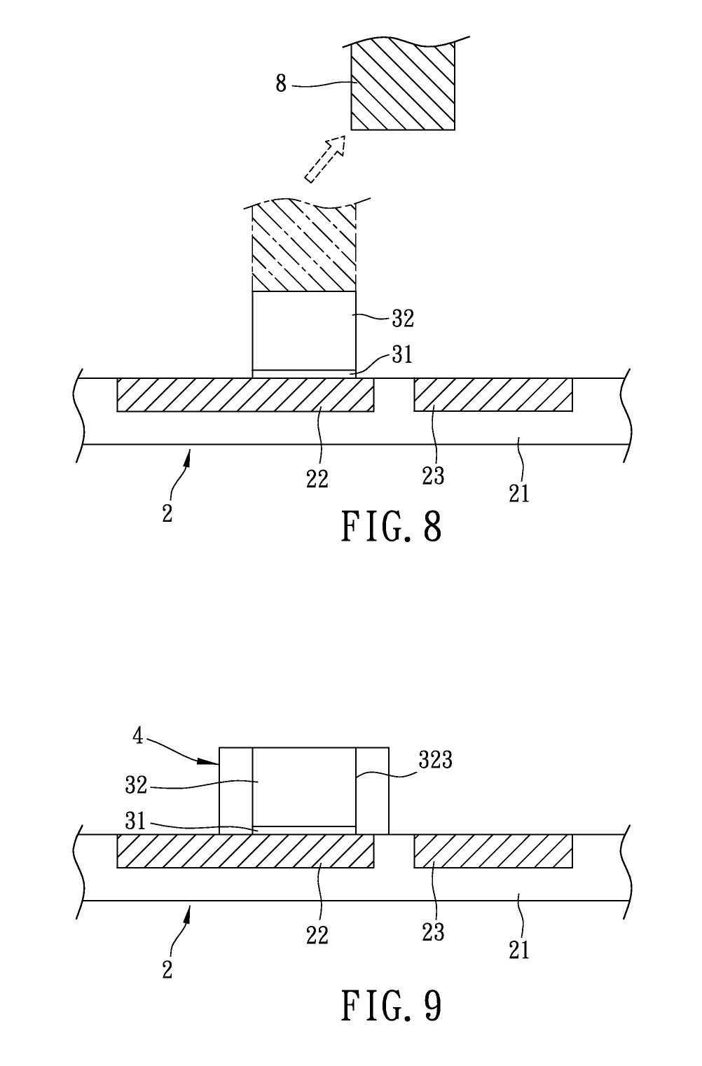

Referring to FIG. 8, the temporary substrate 8 is then removed, for example, by a laser lift off process to expose the second polarity side 322 of the light-emitting diode die 32.

Next, referring to FIG. 9, an insulator 4 is formed to surround the surrounding surface 323 of the light-emitting diode die 32 and the electrode layer 31.

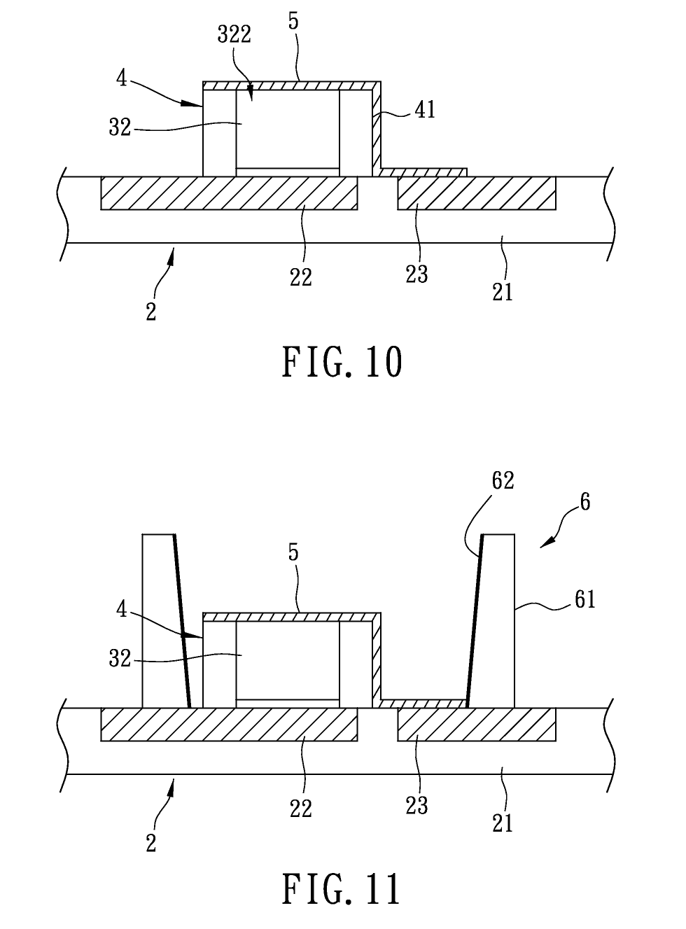

Thereafter, referring to FIG. 10, a transparent conductive layer 5 is formed. The transparent conductive layer 5 contacts and extends from the second polarity side 322 of the light-emitting diode die 32, along an outer surface 41 of the insulator 4, to the second conductor 23, so that the second polarity side 322 of the light-emitting diode die 32 is electrically connected to the second conductor 23 through the transparent conductive layer 5.

Then, referring to FIG. 11, a reflecting cup 6 is adapted to reflect light and is formed on the permanent substrate 2 to enclose the light-emitting diode die 32, the insulator 4, and the transparent conductive layer 5. A surrounding wall 61 is formed using a lithography process. The surrounding wall 61 surrounds the light-emitting diode die 32, the insulator 4, and the transparent conductive layer 5. Next, a reflective material is formed using a sputtering process on an inner surface of the surrounding wall 61 to obtain a reflective layer 62.

Finally, referring to FIG. 3, alight-transmissive encapsulant 7 is filled, for example, by a dispensing process, in a space defined by the reflecting cup 6 and the substrate 2 to encapsulate and isolate the light-emitting diode die 32, the insulator 4, and the transparent conductive layer 5 from the external environment. The light-emitting diode device of the present invention is thus obtained.

From the aforementioned method, it is evident that the light-emitting diode device of the present invention is made using a precise semiconductor process technique and microelectromechanical systems (MEMS). Compared with the conventional light-emitting diode device having a reflecting cup that is made by an injection molding process and that is limited in line-width of the injection molding process, the light-emitting diode device of this invention, in which the reflecting cup 6 is made by a lithography process and MEMS, may be miniaturized and planarized.

Besides, the reflecting cup (i.e., the cup member 11 shown in FIG. 2) of the conventional light-emitting diode device is formed by injection molding, and the light-emitting diode die is formed using semiconductor equipments. Thus, in the past, the step for forming the light emitting diode die and the step for forming the reflecting cup should be conducted in different equipments. Since the reflecting cup 6 of the light-emitting diode device according to this invention can be formed using the semiconductor equipments, the light-emitting diode device of this invention can be formed by continuous processes.

To sum up, since the light emitting from the light-emitting diode die 32 of the present invention will not blocked by wires and/or electrodes, the light emitting efficiency can be dramatically improved. In addition, since the light-emitting diode device of the present invention is made using a semiconductor process technique and MEMS that are relatively precise, miniaturization and planarization of the light-emitting diode device can be achieved.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A light-emitting diode device, comprising:
a substrate including first and second conductors that are spaced apart from each other and that are adapted for connection to an external circuit;
a light-emitting diode die disposed on said substrate and including first and second polarity sides that have opposite polarities, and a surrounding surface that is formed between said first and second polarity sides, said first polarity side being electrically connected to said first conductor;
an insulator disposed around said surrounding surface of said light-emitting diode die;
a transparent conductive layer extending from said second polarity side of said light-emitting diode die oppositely of said substrate, along an outer surface of said insulator, and to said second conductor, so that said second polarity side is electrically connected to said second conductor through said transparent conductive layer; and
a reflecting cup formed on said substrate to define a space with said substrate, said light-emitting diode die, said insulator and said transparent conductive layer being disposed in said space.

2. The light-emitting diode device of claim 1, wherein said transparent conductive layer has a thickness not less than 200 nm.

3. The light-emitting diode device of claim 1, wherein said transparent conductive layer has a thickness not less than 300 nm.

4. The light-emitting diode device of claim 1, wherein said insulator is made of a material selected from the group consisting of silicon oxide, silicon oxynitride, and magnesium fluoride.

5. The light-emitting diode device of claim 1, wherein said transparent conductive layer is made of a material selected from the group consisting of indium tin oxide, indium oxide, tin oxide, nickel oxide, zinc oxide, and magnesium oxide.

6. The light-emitting diode device of claim 1, further comprising a light-transmissive encapsulant that is filled in said space defined by said reflecting cup and said substrate to encapsulate said light-emitting diode die, said insulator and said transparent conductive layer.

7. The light-emitting diode device of claim 6, wherein said light-transmissive encapsulant includes light-transmissive colloidal particles and fluorescent powders.

8. The light-emitting diode device of claim 1, wherein said reflecting cup includes a surrounding wall that surrounds said light-emitting diode die, said insulator and said transparent conductive layer, and a reflecting layer that is formed on an inner surface of said surrounding wall.

9. The light-emitting diode device of claim 8, wherein said surrounding wall is made of a photoresist material, and said reflecting layer is formed by sputtering a reflective material selected from the group consisting of reflective metals, reflective alloys, and combinations thereof.

10. The light-emitting diode device of claim 1, further comprising an electrode layer that is disposed between said light-emitting diode die and said substrate, and that is surrounded by said insulator, said first polarity side of said light-emitting diode die being electrically connected to said first conductor through said electrode layer.

11. A method for fabricating a light-emitting diode device, comprising:
(a) forming over a temporary substrate a light-emitting diode die which has first and second polarity sides having opposite polarities and a surrounding surface that is formed between the first and second polarity sides;
(b) preparing a permanent substrate which includes an insulating base, and first and second conductors that are separately formed on the insulating base;
(c) mounting the light-emitting diode die on the permanent substrate such that the first polarity side of the light-emitting diode die, which is disposed opposite to the temporary substrate, is electrically connected to the first conductor of the permanent substrate, and the light-emitting diode die is spaced apart from the second conductor, followed by removing the temporary substrate to expose the second polarity side of the light-emitting diode die;
(d) forming an insulator to surround the surrounding surface of the light-emitting diode die;
(e) forming a transparent conductive layer that extends from the second polarity side of the light-emitting diode die, along an outer surface of the insulator, to the second conductor, so that the second polarity side of the light-emitting diode die is electrically connected to the second conductor through the transparent conductive layer; and
(f) forming a reflecting cup on said permanent substrate to enclose the light-emitting diode die, the insulator, and the transparent conductive layer.

12. The method of claim 11, wherein the transparent conductive layer has a thickness not less than 200 nm.

13. The method of claim 11, wherein the transparent conductive layer has a thickness not less than 300 nm.

14. The method of claim 11, wherein the step (f) includes:
i) forming a surrounding wall using a lithography process, the surrounding wall surrounding the light-emitting diode die, the insulator, and the transparent conductive layer; and
ii) forming a reflective material using a sputtering process on an inner surface of the surrounding wall to obtain a reflective layer.

15. The method of claim 11, further comprising, after step (f):
(g) filling a light-transmissive encapsulant in a space defined by the reflecting cup and the substrate to encapsulate the light-emitting diode die, the insulator, and the transparent conductive layer.

16. The method of claim 11, further comprising:
(h) forming an electrode layer over the first polarity side before step (c), so that the first polarity side is electrically connected to the first conductor through the electrode layer after step (c).
